(19) United States
(12) Patent Application Publication
(10) Pub. No.: US 2025/0197127 A1
(43) Pub. Date: Jun. 19, 2025

(54) Article Transport Facility

(71) Applicant: Daifuku Co., Ltd., Osaka-shi (JP)

(72) Inventors: Makoto Kono, Komaki-shi (JP); Koichi Hagiwara, Komaki-shi (JP)

(21) Appl. No.: 18/981,214

(22) Filed: Dec. 13, 2024

(30) Foreign Application Priority Data
Dec. 14, 2023 (JP) 2023-211369

(51) Int. Cl. B65G 43/10; B61B 3/02; B61L 27/04; B65G 35/06

(52) U.S. Cl. CPC B65G 43/10; B61B 3/02; B61L 27/04; B65G 35/06

(57) ABSTRACT

An article transport facility includes a control system. The control system is configured to perform an entry permission issuing process of giving an entry permission to enter a junction to X entry-waiting transport vehicles among entry-waiting transport vehicles in a first pre-junction section, wherein X=N1−N2+M, where X is the number of entry-waiting transport vehicles receiving the entry permission, N1 is a first number indicative of the number of the entry-waiting transport vehicles in the first pre-junction section, N2 is a second number indicative of the number of entry-waiting transport vehicles in a second pre-junction section, and M is an adjustment number as a numeral of 0 or more.

### CROSS-REFERENCE TO RELATED APPLICATION

This application claims priority to Japanese Patent Application No. 2023-211369 filed Dec. 14, 2023, the disclosure of which is hereby incorporated by reference in its entirety.

### BACKGROUND OF THE INVENTION

### 1. Field of the Invention

The present invention relates to an article transport facility including a plurality of transport vehicles moving along a predetermined path.

### 2. Description of Related Art

Japanese Unexamined Patent Application Publication No. 2018-128914 (No. JP 2018-128914) discloses an example of the article transport facility. In the article transport facility of JP 2018-128914, a first stop position (P3) and a second stop position (P4) are set on the upstream side from a junction position (P2), and a transport vehicle (3) entering a pre-junction section including the second stop position (P4), for example, waits at the second stop position (P4) until the transport vehicle (3) is allowed to enter a junction including the junction position (P2).

In the article transport facility of JP 2018-128914, even when a great number of transport vehicles stop in the pre-junction section including the second stop position, transport vehicles stopping in a pre-junction section including the first stop position and the transport vehicles stopping in the pre-junction section including the second stop position are allowed to enter the junction on the same condition. Accordingly, an uneven state where the number of transport vehicles stopping in the pre-junction section including the second stop position is large continues, and transport vehicles that cannot enter the pre-junction section including the second stop position might cause a traffic jam in a section on the upstream side from the pre-junction section. Such a traffic jam might cause a decrease in article transport efficiency in the whole article transport facility.

### SUMMARY OF THE INVENTION

In view of the foregoing, an article transport facility that easily restrains the occurrence of a traffic jam in a section on the upstream side from a pre-junction section is desired.

An article transport facility according to this disclosure includes; a plurality of transport vehicles each configured to move along a predetermined path and transport an article; and a control system configured to control the plurality of transport vehicles. The path includes a junction at which two pre-junction sections are merged into one post-junction section, the two pre-junction sections including a first pre-junction section and a second pre-junction section, the first pre-junction section having more entry-waiting transport vehicles waiting to enter the junction than the second pre-junction section. The control system is configured to perform an entry permission issuing process of giving an entry permission to enter the junction to X entry-waiting transport vehicles among the entry-waiting transport vehicles in the first pre-junction section, wherein X=N1−N2+M, where X is the number of entry-waiting transport vehicles receiving the entry permission, N1 is a first number indicative of the number of the entry-waiting transport vehicles in the first pre-junction section, N2 is a second number indicative of the number of entry-waiting transport vehicles in the second pre-junction section, and M is an adjustment number as a numeral of 0 or more.

In this configuration, a larger number of transport vehicles in a pre-junction section with a larger number of entry-waiting transport vehicles can preferentially receive the entry permission to enter the junction, thereby making it possible to reduce inequality in the number of entry-waiting transport vehicles between the two pre-junction sections. This can reduce such a possibility that the number of entry-waiting transport vehicles in either of the pre-junction sections is too large, and this influences the movement of other transport vehicles in a section on the upstream side from the pre-junction section. This accordingly makes it possible to easily restrain the occurrence of a traffic jam in the section on the upstream side from the pre-junction section.

### BRIEF DESCRIPTION OF THE DRAWINGS

FIG. 1 is a schematic view illustrating an article transport facility according to an embodiment;

FIG. 2 is a schematic view illustrating a transport vehicle in FIG. 1;

FIG. 3 is a schematic view to describe an entry permission issuing process in the article transport facility of FIG. 1;

FIG. 4 is a schematic view illustrating a state subsequent to FIG. 3;

FIG. 5 is a schematic view illustrating a state subsequent to FIG. 4; and

FIG. 6 is a schematic view to describe an entry permission issuing process in the article transport facility of FIG. 1.

### DESCRIPTION OF THE INVENTION

The following describes an article transport facility 10 according to a first embodiment with reference to the drawings.

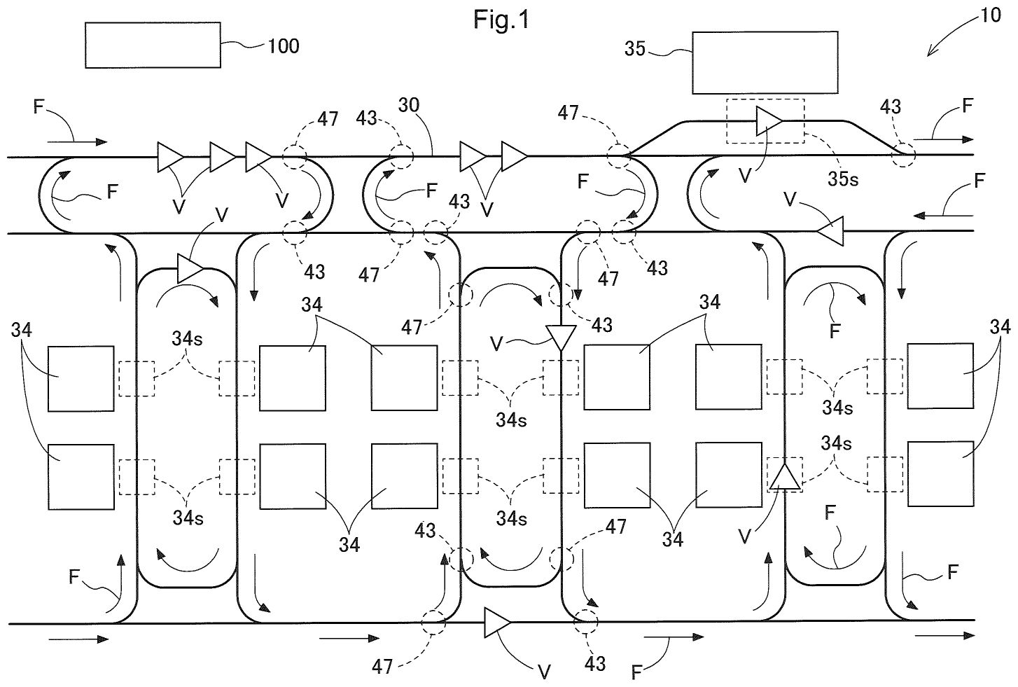

FIG. 1 is a view illustrating an example of an article transport facility 10 according to the present embodiment. As simply illustrated in FIG. 1, the article transport facility 10 includes a plurality of transport vehicles V each configured to move along a predetermined path 30 and transport an article U. The path 30 is a path (travel path) where the transport vehicle V is movable. The path 30 indicates a whole path on which the transport vehicle V travels. The path 30 is constituted by a set of a plurality of paths (partial paths).

The article transport facility 10 includes a control system 100 configured to control the plurality of transport vehicles V. Each function of the control system 100 is implemented by collaboration of hardware such as an arithmetic processing unit with a program executed on the hardware, for example. The whole control system 100 may be provided for the transport vehicle V, or part of the control system 100 may be provided for the transport vehicle V, and the other part of the control system 100 may be provided for an external control device (a control device provided outside the transport vehicle V and communicable with the transport vehicle V). The whole control system 100 may be provided for an external control device. Here, the external control device may not be one device and may be a set of a plurality of devices communicable with each other. The control system 100 controls traveling of each of the plurality of transport vehicles V to reach its destination. Examples of the “destination of a transport vehicle” include a station at a transport source (described later), a station at a transport destination, and the like.

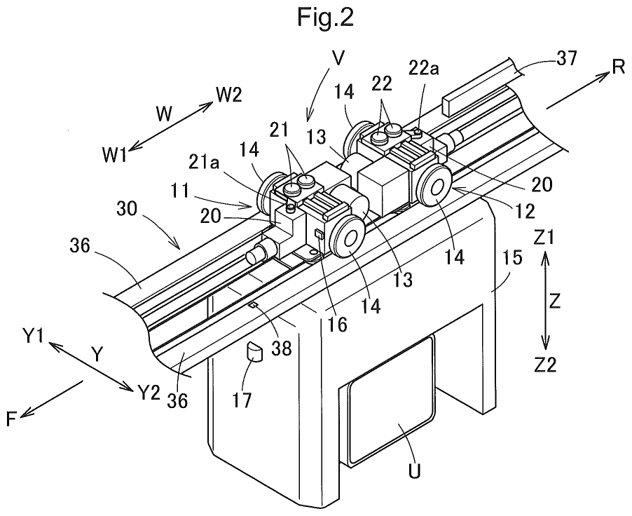

FIG. 2 is a view illustrating an example of the transport vehicle V. The transport vehicle V includes a controller (a device controller) configured to control a traveling drive unit 13 and a guide drive unit 20 (described later). In a case where at least part of the control system 100 is provided for an external control device, the controller of the transport vehicle V works in response to a command from the external control device. In a case where at least part of the control system 100 is provided for the transport vehicle V, the controller of the transport vehicle V may constitute the at least part of the control system 100.

As illustrated in FIG. 2, a direction along the path 30 is defined a travel direction W, and a direction (herein, a horizontal direction perpendicular to the travel direction W) perpendicular to the travel direction W as viewed vertically along an up-down direction Z (vertical direction) is defined as a width direction Y. As illustrated in FIG. 1, each portion of the path 30 has a forward direction F. A direction opposite from the forward direction F is defined as a reverse direction R (see FIG. 2), and the transport vehicle V basically travels in the forward direction F on the path 30. In the present embodiment, the path 30 allows the transport vehicle V to travel in the forward direction F to circulate between the transport source and the transport destination of the article U.

As illustrated in FIG. 2, a side toward the forward direction F along the path 30 is defined as a downstream side W1, and a side toward the reverse direction R along the path 30 is defined as an upstream side W2. The travel direction W can be rephrased as a front-rear direction of the transport vehicle V, the downstream side W1 can be rephrased as a front side of the transport vehicle V, and the upstream side W2 can be rephrased as a rear side of the transport vehicle V. One side (herein, the right side when the transport vehicle V faces the forward direction F) in the width direction Y is defined as a first side Y1 in the width direction, and the other side (herein, the left side when the transport vehicle V faces the forward direction F) in the width direction Y is defined as a second side Y2 in the width direction.

The transport vehicle V travels along the path 30 and transports the article U. The article U is, for example, a FOUP (Front Opening Unified Pod) storing a semiconductor wafer. The transport vehicle V is an unmanned transport vehicle. The transport vehicle V may include wheels or may not include wheels. The path 30 may be formed physically or may be formed virtually. In the present embodiment, the path 30 is physically formed of traveling rails 36 (a pair of traveling rails 36 disposed at an interval in the width direction Y). The traveling rails 36 are supported in such a manner as to hang from a ceiling, for example.

FIG. 2 assumes a case where the path 30 is formed along the ceiling, but the path 30 may be formed on a floor face or the like. In a case where the path 30 is formed on a floor face, the path 30 is physically formed of rails or a passage provided on the floor face, for example, or the path 30 is virtually formed of a two-dimensions code, an RF (Radio Frequency) tag, a magnetic tape, or the like provided on the floor face. The path 30 may be a path calculated based on a result of recognition of the environment around the transport vehicle V. Note that the floor face may be a floor face supported in such a manner as to hang from the ceiling.

As illustrated in FIG. 2, the transport vehicle V includes a first travel unit 11 as a travel unit. The first travel unit 11 includes travel wheels 14 configured to roll on travel surfaces (herein, surfaces facing the upper side Z1) of the traveling rails 36, and a traveling drive unit 13 (an electric motor such as a servomotor, for example) configured to rotate the travel wheels 14. When the travel wheels 14 are rotated by the traveling drive unit 13, the first travel unit 11 travels along the traveling rails 36. In the present embodiment, the transport vehicle V further includes a second travel unit 12 on the upstream side W2 relative to the first travel unit 11. The second travel unit 12 is configured similarly to the first travel unit 11 and travels along the traveling rails 36 in response to the travel wheels 14 rotated by the traveling drive unit 13.

The transport vehicle V includes a main body 15 connected to the first travel unit 11. The article U is stored in the main body 15 and transported by the transport vehicle V. In the present embodiment, the main body 15 is disposed on the lower side Z2 relative to the first travel unit 11 and supported by the first travel unit 11. In the present embodiment, the main body 15 is connected to both the first travel unit 11 and the second travel unit 12. The main body 15 is disposed on the lower side Z2 relative to the first travel unit 11 and the second travel unit 12 and supported by the first travel unit 11 and the second travel unit 12.

In the example illustrated in FIG. 2, the transport vehicle V includes a collision prevention sensor 17 configured to detect another transport vehicle V present on the downstream side W1 relative to the transport vehicle V. When the collision prevention sensor 17 detects another transport vehicle V, the transport vehicle V including the collision prevention sensor 17 decelerates or stops to avoid a collision with the another transport vehicle V.

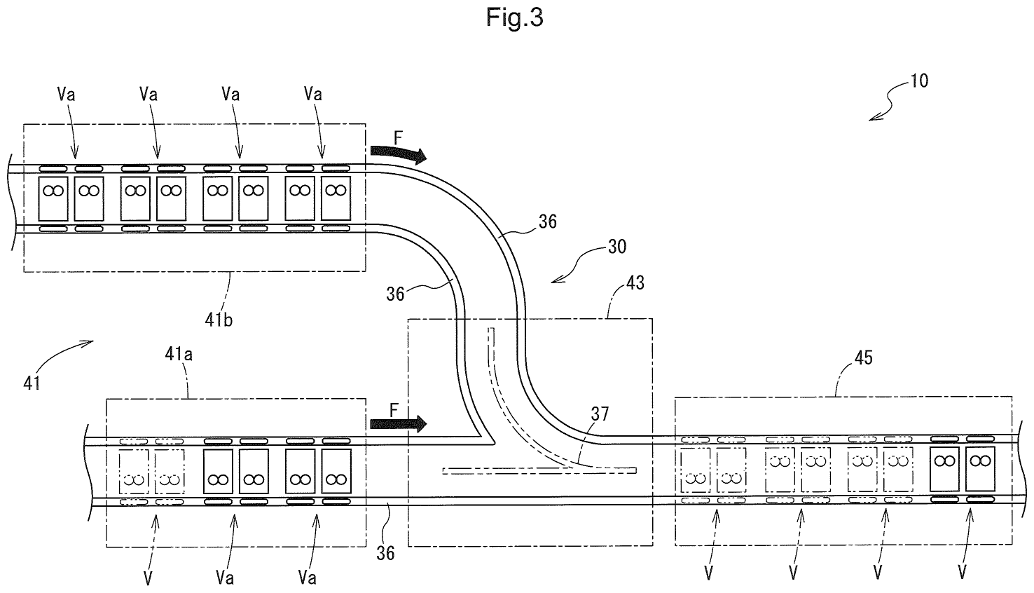

As illustrated in FIG. 2, in the present embodiment, information retainers 38 such as a two-dimensional code or an RF tag are provided at a plurality of points on the path 30. The information retainer 38 is provided, for example, at a point that can be a stop position for the transport vehicle V, e.g., a station (described later), a pre-junction section 41 (see FIG. 3), a post-junction section 45 (see FIG. 3), and the like. The information retainer 38 stores positional information as information indicative of the position where the information retainer 38 is provided. The transport vehicle V includes a reader 16 configured to read the positional information stored in the information retainer 38 and recognizes a current position of the transport vehicle V based on the positional information thus read by the reader 16. The transport vehicle V recognizes its current position, for example, based on the positional information read by the reader 16, and a travel distance after the reader 16 reads the positional information. The travel distance of the transport vehicle V is measured by use of a rotary encoder, for example. Note that the transport vehicle V can be configured to recognize its current position based on an output from a positioning device such as a GNSS (Global Navigation Satellite System) receiver.

The control system 100 grasps the current position of each of the plurality of transport vehicles V. In the present embodiment, the transport vehicle V is configured to recognize its current position in the manner described earlier, and the control system 100 grasps the current position of each of the plurality of transport vehicles V by acquiring, from the each of the plurality of transport vehicles V, information on the current position of the each of the plurality of the transport vehicles V. The control system 100 may be configured to grasp a number N of entry-waiting transport vehicles Va (described later), the number of transport vehicles V in the pre-junction section 41, the number of transport vehicles V in the junction 43, or the number of transport vehicles V in the post-junction section 45, by acquiring, from each of the transport vehicles V, the information on the current position of the each of the transport vehicles V.

A plurality of stations each serving as a destination for the transport vehicle V is set on the path 30. The transport vehicle V transfers the article U to and from an article support provided in the station. The operation of the transport vehicle V includes a traveling operation to travel along the path 30, an operation to receive the article U from the article support in the station, and an operation to unload the article U to the article support in the station. After the transport vehicle V travels to a station of a transport source and receives the article U at the station, the transport vehicle V travels to a station of a transport destination and unloads the article U at the station.

Examples of the “article support” include a load port of a processing device 34 configured to perform machining, assortment, and the like on the article U, an inbound-outbound port of a storage device 35, a storage shelf (not illustrated) for temporarily storing the article U, and so on. The article support is placed right under the path 30 in a station, for example.

The “destination” of the transport vehicle V includes a processing-device station 34s for the transport vehicle V to transfer the article U to and from the processing device 34 (illustrated in FIG. 1) configured to perform processing on the article U. The “destination” of the transport vehicle V includes a storage-device station 35s for the transport vehicle V to transfer the article U to and from the storage device 35 (illustrated in FIG. 1) configured to store the article U. The destination of the transport vehicle V may include a maintenance station (not illustrated) for the transport vehicle V.

As illustrated in FIG. 2, a guide rail 37 is provided in some sections on the path 30. In the present embodiment, the guide rail 37 is disposed on the upper side Z1 relative to the traveling rails 36. In the present embodiment, the guide rail 37 is disposed, in the width direction Y, between the pair of the traveling rails 36 disposed at an interval in the width direction Y.

The transport vehicle V includes a guided section (21, 22) to be guided by the guide rail 37 in contact with the guide rail 37 from either side in the width direction Y, and a guide drive unit 20 (for example, a solenoid or an electric motor) configured to move the guided section in the width direction Y. The movement of the guided section in the width direction Y by the guide drive unit 20 is performed, for example, by driving only the guided section in the width direction Y, or by driving the guided section in the width direction Y together with a support for supporting the guided section.

In the present embodiment, the first travel unit 11 includes, as the guided section, a first guide wheel 21 configured to rotate (herein, freely move) around an axis along the up-down direction Z, and the guide drive unit 20 provided in the first travel unit 11 moves the first guide wheel 21 in the width direction Y. In the example illustrated in FIG. 2, the first travel unit 11 includes two first guide wheels 21 arranged in the travel direction W, and the guide drive unit 20 moves the two first guide wheels 21 in the width direction Y by moving a support supporting the two first guide wheels 21 in the width direction Y.

In the present embodiment, the second travel unit 12 includes, as the guided section, a second guide wheel 22 configured to rotate (herein, freely move) around an axis along the up-down direction Z, and the guide drive unit 20 provided in the second travel unit 12 moves the second guide wheel 22 in the width direction Y. In the example illustrated in FIG. 2, the second travel unit 12 includes two second guide wheels 22 arranged in the travel direction W, and the guide drive unit 20 moves the two second guide wheels 22 in the width direction Y by moving a support supporting the two second guide wheels 22 in the width direction Y. In the following description, in a case of describing common matters between the first guide wheel 21 and the second guide wheel 22, they are not distinguished from each other and will be collectively described as a “guide wheel.”

The transport vehicle V includes a movement detection unit configured to detect movement of the guide wheel in the width direction Y. In the present embodiment, the first guide wheel 21 and the second guide wheel 22 are guide wheels, and a first movement detection unit 21a and a second movement detection unit 21b are movement detection units. The control system 100 detects the movement of the guide wheel in the width direction Y by acquiring a detection result of the movement of the guide wheel in the width direction Y from the movement detection unit.

FIG. 3 is a view illustrating an example of the junction 43 provided for the path 30. The reverse direction R, the travel direction W, the downstream side W1, the upstream side W2, the width direction Y, the first side Y1 in the width direction, and the second side Y2 in the width direction are determined based on the forward direction F that is a travel direction to merge with the junction 43, and therefore, they are omitted in FIG. 3, and only the forward direction F is illustrated. The path 30 includes the junction 43 at which two pre-junction sections 41 are merged into one post-junction section 45. The path 30 includes a branch 47 (see FIG. 1) at which one pre-junction section branches into two post-junction sections.

The pre-junction section 41 is a section determined in advance for each junction 43. The two pre-junction sections 41 are part of the path 30 and each may be a single region. One or both of the two pre-junction sections 41 may be constituted by a plurality of regions. The pre-junction section 41 may include the post-junction section 45 on the upstream side W2 from the pre-junction section 41. In the present embodiment, the pre-junction section 41 is a section that does not include the junction 43 on the upstream side W2 from the pre-junction section 41. The pre-junction section 41 does not include other pre-junction sections 41. The pre-junction section 41 does not include the station. The pre-junction section 41 is a section including no guide rail 37. In the example illustrated herein, the pre-junction section 41 is a linear section.

In the present embodiment, an end portion of the pre-junction section 41 which end portion is on the upstream side W2 is a spot at which the transport vehicle V sends, to the control system 100, a passage permission request to request a permission to pass the junction 43. An end portion of the pre-junction section 41 which end portion is on the downstream side W1 is a spot at which a topmost transport vehicle V waiting for entering the junction 43 stops.

The post-junction section 45 is a section determined in advance for each junction 43. The post-junction section 45 is part of the path 30 and may be a single region. The post-junction section 45 may be constituted by a plurality of regions. The post-junction section 45 may include the pre-junction section 41 on the downstream side W1 from the post-junction section 45. In the present embodiment, the post-junction section 45 is a section including no junction 43 on the downstream side W1 from the post-junction section 45. The post-junction section 45 does not include other post-junction sections 45. The post-junction section 45 does not include the station. The post-junction section 45 is a section including no guide rail 37. In the example illustrated herein, the post-junction section 45 is a straight section.

Here, one of the two pre-junction sections 41 which one has a larger number N of entry-waiting transport vehicles Va as transport vehicles V waiting for entering the junction 43 is referred to as a “first pre-junction section,” and the other one is referred to as a “second pre-junction section.” In the state of FIG. 3, the pre-junction section 41b is the first pre-junction section, and the pre-junction section 41a is the second pre-junction section.

Examples of the entry-waiting transport vehicle Va include a transport vehicle V stopping in the pre-junction section 41, a transport vehicle V traveling in the pre-junction section 41, and the like. The entry-waiting transport vehicles Va may include a transport vehicle V traveling in a section on the upstream side W2 from the pre-junction section 41. The entry-waiting transport vehicle Va is acquired by various sensors, an imaging device (not illustrated) configured to capture an image of the pre-junction section 41, image recognition, and the like, for example. The control system 100 acquires respective numbers N of entry-waiting transport vehicles Va in the two pre-junction sections 41 and determines a pre-junction section with a larger number N of entry-waiting transport vehicles Va out of the two pre-junction sections 41 as the first pre-junction section and the other one of them as the second pre-junction section.

In a case where the control system 100 performs an entry permission issuing process of giving an entry permission to allow a plurality of entry-waiting transport vehicles Va to enter the junction 43, the control system 100 gives the entry permission to entry-waiting transport vehicles Va corresponding to an entry permission number X among the entry-waiting transport vehicles Va in the first pre-junction section. The entry permission number X can be expressed by Formula (1) as follows:

$$X = N 1 - N 2 + M , \qquad ( 1 )$$

where N1 is a first number indicative of the number N of entry-waiting transport vehicles Va in the first pre-junction section, N2 is a second number indicative of the number N of entry-waiting transport vehicles Va in the second pre-junction section, and M is an adjustment number as a numeral of 0 or more.

In the example illustrated in FIG. 3, the adjustment number M is 0. Accordingly, in a case where the first number N1 is 4 and the second number N2 is 2, the entry permission number X is 2. In the example illustrated in FIG. 3, in a case where the adjustment number M is 1, the entry permission number X is 3. Note that the adjustment number M is a given value and may be 3, 4, or the like, for example, or the adjustment number M may be a value varying depending on the junction 43. Examples of the adjustment number M include a numeral of 0 or more, a numeral of 1 or more, an integer of 0 or more, an integer of 1 or more, an integer of 2 or more, and the like. In a case where the value of the entry permission number X calculated by Formula (1) is not an integer, the value is rounded up, rounded down, or rounded off.

In the present embodiment, in the entry permission issuing process, the control system 100 gives the entry permission to the entry-waiting transport vehicles Va corresponding to the entry permission number X at the same time, but the control system 100 may give the entry permission to them at a time interval. In the present embodiment, in the entry permission issuing process, the entry permission is given to the entry-waiting transport vehicles Va corresponding to the entry permission number X from an entry-waiting transport vehicle Va closest to the junction 43, but the entry permission may be given regardless of a distance from the junction 43.

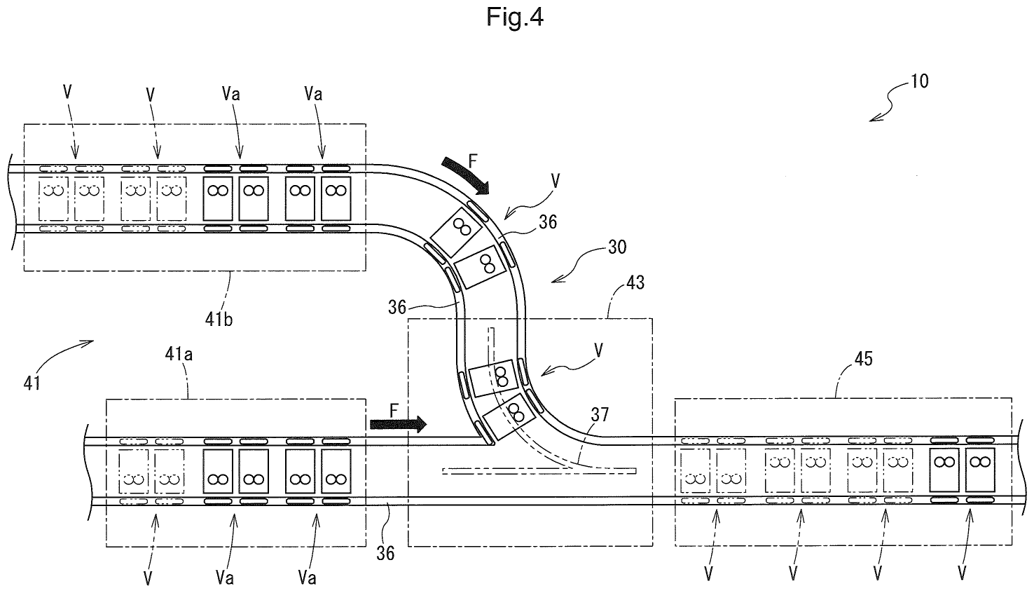

FIG. 4 illustrates an example after the entry permission issuing process is performed but just before a subsequent entry permission issuing process is performed. After the control system 100 performs the entry permission issuing process and all the entry-waiting transport vehicles Va receiving the entry permission by the entry permission issuing process exit from the first pre-junction section, the control system 100 performs a subsequent entry permission issuing process. Note that the subsequent entry permission issuing process may be performed before all the entry-waiting transport vehicles Va exit from the junction 43. This allows the transport vehicles V to efficiently enter the junction 43. The subsequent entry permission issuing process may be performed after all the entry-waiting transport vehicles Va exit from the junction 43. This allows the transport vehicles V to safely enter the junction 43.

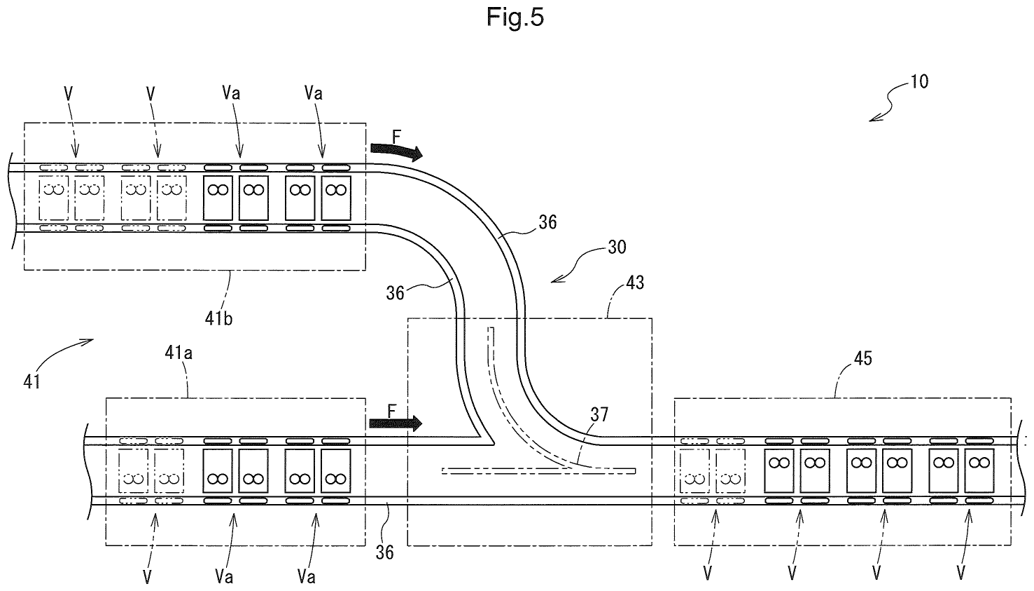

FIG. 5 is a view illustrating a state subsequent to FIG. 4 and illustrates a state where all the entry-waiting transport vehicle Va receiving the entry permission by the entry permission issuing process enter the post-junction section 45. After the control system 100 performs the entry permission issuing process and all the entry-waiting transport vehicles Va receiving the entry permission by the entry permission issuing process enter the post-junction section 45, the control system 100 may perform a subsequent entry permission issuing process.

FIG. 5 illustrates an example in which the two pre-junction sections 41 have the same number N of entry-waiting transport vehicles Va. In the entry permission issuing process, in a case where the two pre-junction sections 41 have the same number N of entry-waiting transport vehicles Va, the control system 100 gives the entry permission to entry-waiting transport vehicles Va corresponding to the number of transport vehicles which number is obtained by adding at least one to the adjustment number M, from among the entry-waiting transport vehicles Va in a pre-junction section 41 satisfying a predetermined condition out of the two pre-junction sections 41. In the example illustrated in FIG. 5, in a case where the adjustment number M is 0, the control system 100 gives the entry permission to one entry-waiting transport vehicle Va the number of which is obtained by adding one to the adjustment number M, and in a case where the adjustment number M is 1, the control system 100 gives the entry permission to two entry-waiting transport vehicles Va the number of which is obtained by further adding one to the adjustment number M.

Examples of the “pre-junction section satisfying a predetermined condition” include a pre-junction section 41 with a topmost entry-waiting transport vehicle Va having a longer waiting time, either of the pre-junction sections 41 changed alternately every time the entry permission issuing process is performed, either one of the pre-junction sections 41, a pre-junction section 41 with a smaller number of transport vehicles V allowed to enter the junction 43 out of the two pre-junction sections 41, a pre-junction section 41 with a shorter length out of the two pre-junction sections 41, and the like. In the example illustrated herein, the number of transport vehicles V allowed to enter the junction 43 in the pre-junction section 41 is indicated by the number of transport vehicles V illustrated by an alternate long and two short dashes line in the pre-junction section 41. The number of transport vehicle V allowed to enter the junction 43 in the pre-junction section 41 is a value obtained by subtracting the number of transport vehicles V waiting in the pre-junction section 41 from an upper limit for the number of transport vehicles V allowed to wait in the pre-junction section 41.

An actual length of the pre-junction section 41 may be used as the length of the pre-junction section 41, or the upper limit for the number of transport vehicles V allowed to wait in the pre-junction section 41 may be used. In the example illustrated herein, the upper limit in the pre-junction section 41a is three, and the upper limit in the pre-junction section 41b is four.

In a case where the value of the entry permission number X exceeds a predetermined entry upper limit Xa, the control system 100 performs the entry permission issuing process with the use of the entry upper limit Xa instead of the value of the entry permission number X. Examples of the entry upper limit Xa include a value set for each pre-junction section 41, a value set for each post-junction section 45, a value set for each junction 43, and the like.

In a case where the value of the entry permission number X is less than a predetermined entry lower limit Xb, the control system 100 performs the entry permission issuing process with the use of the entry lower limit Xb instead of the value of the entry permission number X. Examples of the entry lower limit Xb include a value set for each pre-junction section 41, a value set for each post-junction section 45, a value set for each junction 43, and the like.

The control system 100 acquires information on an entry-permittable number Xc indicative of the number of transport vehicles V allowed to enter the post-junction section 45, and in a case where the entry permission number X exceeds the entry-permittable number Xc, the control system 100 performs the entry permission issuing process with the use of a value equal to or less than the entry-permittable number Xc instead of the value of the entry permission number X. In the present embodiment, the control system 100 performs the entry permission issuing process with the use of the value of the entry-permittable number Xc instead of the value of the entry permission number X. The control system 100 periodically acquires information on the entry-permittable number Xc.

Examples of the entry-permittable number Xc include a value obtained by subtracting the number of transport vehicles V actually waiting in the post-junction section 45 from an upper limit for the number of transport vehicles V allowed to wait in the post-junction section 45, a value set for each post-junction section 45, and the like. The entry-permittable number Xc may be acquired by an imaging device (not illustrated) configured to capture an image of the post-junction section 45 and image recognition, or may be calculated based on values given by various sensors, a set value, or the like. In the example illustrated herein, the entry-permittable number Xc is indicated by the number of transport vehicles V illustrated by an alternate long and two short dashes line in the post-junction section 45. In the example illustrated in FIG. 3, for example, the upper limit for the number of transport vehicles V allowed to wait in the post-junction section 45 is four, and the number of transport vehicles V waiting in the post-junction section 45 is one, so that the entry-permittable number Xc is three.

In the present embodiment, in a case where an entry-waiting transport vehicle Va is waiting for more than a predetermined stopping time in the second pre-junction section, the control system 100 gives the entry permission to the entry-waiting transport vehicle Va in preference to the entry-waiting transport vehicles Va in the first pre-junction section. This makes it possible to avoid such a situation that the entry-waiting transport vehicle Va in the second pre-junction section cannot enter the junction 43 for an excessively long time.

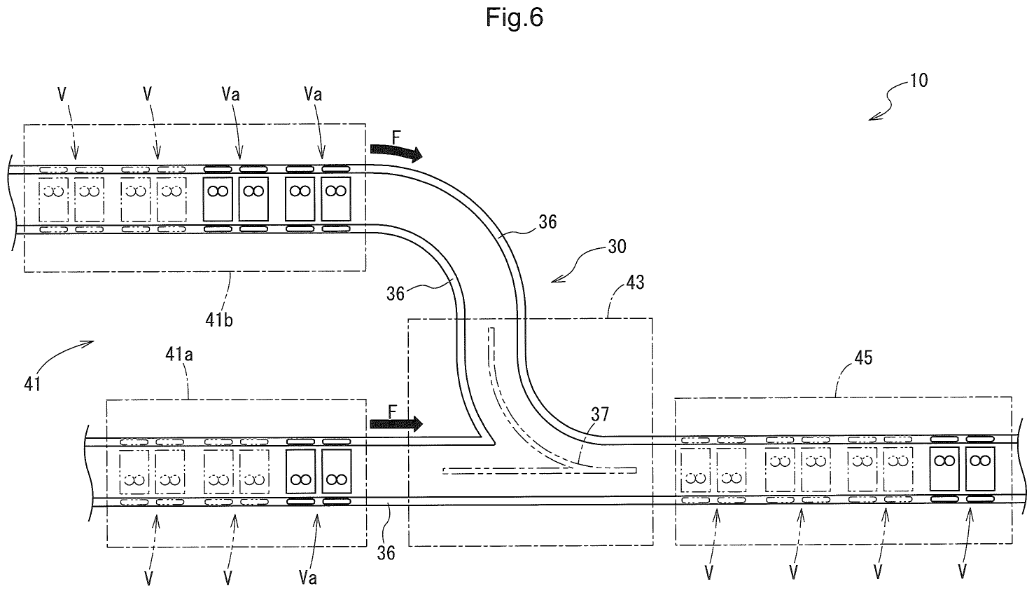

FIG. 6 illustrates an example in which the number N of entry-waiting transport vehicles Va is larger in the pre-junction section 41b than in the pre-junction section 41a. In the present embodiment, in the state of FIG. 6, the pre-junction section 41a is the second pre-junction section, and the pre-junction section 41b is the first pre-junction section. The difference between the first number N1 as the number N of entry-waiting transport vehicles Va in the first pre-junction section and the second number N2 as the number N of entry-waiting transport vehicles Va in the second pre-junction section is 1. Here, in a case where the adjustment number M 1 is an integer of 1 or more, the entry permission number X is 2. Since the control system 100 is configured to give the entry permission to at least two entry-waiting transport vehicles Va, it is possible to increase the article transport efficiency.

The following describes the article transport facility 10 according to a second embodiment, with reference to FIGS. 5 to 6.

The present embodiment is different from the first embodiment in that a corrected number Nk of entry-waiting transport vehicles is used. The following mainly describes differences from the first embodiment. Note that points not described particularly are the same as those in the first embodiment.

In the present embodiment, the control system 100 performs an entry permission issuing process with the use of the corrected number Nk of entry-waiting transport vehicles based on the length of each of the two pre-junction sections 41, and the corrected number Nk of entry-waiting transport vehicles is obtained by correcting the value of the number N of entry-waiting transport vehicles Va in the pre-junction section 41 such that the value is larger as the length of the pre-junction section 41 is shorter.

In the present embodiment, the control system 100 performs at least one of determination on which one of the pre-junction sections 41 is taken as the first pre-junction section and calculation of the entry permission number X, by use of the corrected number Nk of entry-waiting transport vehicles. In the present embodiment, the control system 100 performs both the determination and the calculation with the use of the corrected number Nk of entry-waiting transport vehicles.

In the present embodiment, examples of the corrected number Nk of entry-waiting transport vehicles include a value obtained by adding a correction value K1 increasing as the length of the pre-junction section 41 is shorter to the number N of entry-waiting transport vehicles, a value obtained by multiplying the number N of entry-waiting transport vehicles Va by the correction value K1 increasing as the length of the pre-junction section 41 is shorter, and the like. Examples of the correction value K1 include a numeral of 0 or more, an integer of 1 or more, and the like. The correction value K1 may be directly proportional or may not be directly proportional to the length of the pre-junction section 41.

In the present embodiment, in a case where the two pre-junction sections 41 have the same number N of entry-waiting transport vehicles Va, the control system 100 performs the entry permission issuing process with the use of the corrected number Nk of entry-waiting transport vehicles. In the present embodiment, in a case where the two pre-junction sections 41 have different numbers N of entry-waiting transport vehicles Va, the control system 100 performs the entry permission issuing process with the use of the corrected number Nk of entry-waiting transport vehicles.

In the present embodiment, one of the two pre-junction sections 41 which one has a larger corrected number Nk of entry-waiting transport vehicles is regarded as the first pre-junction section, and the other one is regarded as the second pre-junction section. For example, in the state illustrated in FIG. 5, the two pre-junction sections 41 have the same number N of entry-waiting transport vehicles Va, but the corrected number Nk of entry-waiting transport vehicles is larger as the length of the pre-junction section 41 is shorter, and therefore, a pre-junction section 41 having a shorter length (in the example illustrated herein, the pre-junction section 41a) is regarded as the first pre-junction section.

In the state illustrated in FIG. 6, the number N of entry-waiting transport vehicles Va in a pre-junction section 41 having a longer length (in the example illustrated herein, the pre-junction section 41b) is two. The number N of entry-waiting transport vehicles Va in the pre-junction section 41 having a shorter length (in the example illustrated herein, the pre-junction section 41a) is one. However, for example, in a case where the correction value K1 for the pre-junction section 41 having a longer length (in the example illustrated herein, the pre-junction section 41b) is 0.5, the correction value K1 for the pre-junction section 41 having a shorter length (in the example illustrated herein, the pre-junction section 41a) is 2, and the correction value K1 is added to the number N of entry-waiting transport vehicles, the corrected number Nk of entry-waiting transport vehicles in the pre-junction section 41b is 2.5, and the corrected number Nk of entry-waiting transport vehicles in the pre-junction section 41a is 3. Accordingly, the pre-junction section 41 having a shorter length (in the example illustrated herein, the pre-junction section 41a) is regarded as the first pre-junction section.

In the present embodiment, the entry permission number X is calculated such that a corrected number Nk1 of entry-waiting transport vehicles in the first pre-junction section is used as the first number N1, and a corrected number Nk2 of entry-waiting transport vehicle numbers in the second pre-junction section is used as the second number N2.

In a case where the value of the entry permission number X exceeds a predetermined entry upper limit Xa, the control system 100 performs the entry permission issuing process with the use of the entry upper limit Xa instead of the value of the entry permission number X. Examples of the entry upper limit Xa include a value set for each pre-junction section 41, a value set for each post-junction section 45, a value set for each junction 43, and the like.

In a case where the value of the entry permission number X is less than a predetermined entry lower limit Xb, the control system 100 performs the entry permission issuing process with the use of the entry lower limit Xb instead of the value of the entry permission number X. Examples of the entry lower limit Xb include a value set for each pre-junction section 41, a value set for each post-junction section 45, a value set for each junction 43, and the like.

Next will be described other embodiments of the article transport facility 10.

(1) The first and second embodiments have described, as an example, the configuration in which the pre-junction section 41 is a section determined in advance for each junction 43 and does not include other pre-junction sections 41. However, the present invention is not limited to such an example, and the pre-junction section 41 may include another pre-junction section 41 on the upstream side W2 from the pre-junction section 41, the junction 43, the post-junction section 45, a station, a curve section, and the like, for example.

(2) The first and second embodiments have described, as an example, the configuration in which the post-junction section 45 is a section determined in advance for each junction 43 and does not include other post-junction sections 45. However, the present invention is not limited to such an example, and the post-junction section 45 may include the pre-junction section 41 on the downstream side W1 from the post-junction section 45, the junction 43, another post-junction section 45, a station, a curve section, and the like, for example.

(3) The first and second embodiments have described, as an example, the configuration in which, after the control system 100 performs an entry permission issuing process and all the entry-waiting transport vehicles Va receiving an entry permission by the entry permission issuing process exit from the first pre-junction section, the control system 100 performs a subsequent entry permission issuing process. However, the present invention is not limited to such an example, and the control system 100 may perform the subsequent entry permission issuing process before all the entry-waiting transport vehicles Va receiving the entry permission by its previous entry permission issuing process exit from the first pre-junction section, for example.

(4) The first embodiment has described, as an example, the configuration in which, in the entry permission issuing process, in a case where two pre-junction sections 41 have the same number of entry-waiting transport vehicles Va, the control system 100 gives the entry permission to transport vehicles V corresponding to the number of transport vehicles which number is obtained by adding at least one to the adjustment number M, from among the entry-waiting transport vehicles Va in the pre-junction section 41 satisfying a predetermined condition out of the two pre-junction sections 41. However, the present invention is not limited to such an example, and in a case where the two pre-junction sections 41 have the same number of entry-waiting transport vehicles Va, for example, the entry permission may be given to a plurality of entry-waiting transport vehicles Va in either of the two pre-junction sections 41 at random. For example, the entry permission may be given to the entry-waiting transport vehicles Va corresponding to the number of transport vehicles which number is obtained by adding at least two to the adjustment number M.

(5) The first and second embodiments have described, as an example, the configuration in which, in a case where the value of the entry permission number X exceeds a predetermined entry upper limit Xa, the control system 100 performs the entry permission issuing process with the use of the entry upper limit Xa instead of the value of the entry permission number X. However, the present invention is not limited to such an example, and the entry upper limit Xa may not be determined in advance, for example. For example, the entry permission issuing process may be performed with the use of a value less than the entry upper limit Xa instead of the value of the entry permission number X.

(6) The first and second embodiments have described, as an example, the configuration in which the control system 100 periodically acquires information on the entry-permittable number Xc indicative of the number of transport vehicles V allowed to enter the post-junction section 45, and in a case where the entry permission number X exceeds the entry-permittable number Xc, the control system 100 performs the entry permission issuing process with the use of a value equal to or less than the entry-permittable number Xc instead of the value of the entry permission number X. However, the present invention is not limited to such an example, and the control system 100 may acquire the information on the entry-permittable number Xc during the entry permission issuing process, instead of acquiring the information periodically, for example. For example, the control system 100 may not acquire the information on the entry-permittable number Xc.

(7) The second embodiment has described, as an example, the configuration in which, in a case where two pre-junction sections 41 have the same number N of entry-waiting transport vehicles Va and in a case where two-pre-junction sections have different numbers N of entry-waiting transport vehicles Va, the control system 100 performs the entry permission issuing process with the use of the corrected number Nk of entry-waiting transport vehicles. However, the present invention is not limited to such an example, and in either of the case where two pre-junction sections 41 have the same number N of entry-waiting transport vehicles Va and the case where two pre-junction sections 41 have different numbers N of entry-waiting transport vehicles Va, the control system 100 may perform the entry permission issuing process with the use of the corrected number Nk of entry-waiting transport vehicles, for example. For example, after the first pre-junction section and the second pre-junction section are determined with the use of the corrected number Nk of entry-waiting transport vehicles, the corrected number Nk of entry-waiting transport vehicles may not be used in calculation of the entry permission number X. For example, after the first pre-junction section and the second pre-junction section are determined without the use of the corrected number Nk of entry-waiting transport vehicles, the corrected number Nk of entry-waiting transport vehicles may be used in calculation of the entry permission number X.

(8) The first and second embodiments have described, as an example, the configuration in which only two pre-junction sections 41 are merged into only one post-junction section 45 at the junction 43. However, the present invention is not limited to such an example, and the branch 47 branching to a path different from the post-junction section 45 may be disposed between the pre-junction section 41 and the junction 43 or between the junction 43 and the post-junction section 45, and a transport vehicle V waiting for entering the branch 47 may also wait in the pre-junction section 41, for example. In such a configuration in which the transport vehicle V waiting for entering the branch 47 also waits in the pre-junction section 41, the branch 47 may be considered to be included in the junction 43, and the number of transport vehicles V waiting for entering the branch 47 may be included in the number of entry-waiting transport vehicles Va waiting for entering the junction 43. Three or more pre-junction sections 41 may be merged into one post-junction section 45 at the junction 43, and the entry permission issuing process using the entry permission number X may be performed on at least two pre-junction sections 41 from among the three or more pre-junction sections 41.

(9) Note that the configurations disclosed in the above embodiment can be applied in combination with the configurations disclosed in other embodiments (including combinations of the embodiments described as the other embodiments) as long as no inconsistency occurs. In terms of other configurations, the embodiment disclosed in the present specification is also just an example in all respects. Accordingly, various modifications can be made appropriately as far as it does not deviate from the scope of this disclosure.

The following describes an article transport facility according to this disclosure.

As one aspect, an article transport facility includes: a plurality of transport vehicles each configured to move along a predetermined path and transport an article; and a control system configured to control the plurality of transport vehicles. The path includes a junction at which two pre-junction sections are merged into one post-junction section, the two pre-junction sections including a first pre-junction section and a second pre-junction section, the first pre-junction section having more entry-waiting transport vehicles waiting to enter the junction than the second pre-junction section. The control system is configured to perform an entry permission issuing process of giving an entry permission to enter the junction to X entry-waiting transport vehicles among the entry-waiting transport vehicles in the first pre-junction section, wherein X=N1−N2+M, where X is the number of entry-waiting transport vehicles receiving the entry permission, N1 is a first number indicative of the number of the entry-waiting transport vehicles in the first pre-junction section, N2 is a second number indicative of the number of entry-waiting transport vehicles in the second pre-junction section, and M is an adjustment number as a numeral of 0 or more.

In this configuration, a larger number of transport vehicles in a pre-junction section with a larger number of entry-waiting transport vehicles can preferentially receive the entry permission to enter the junction, thereby making it possible to reduce inequality in the number of entry-waiting transport vehicles between the two pre-junction sections. This can reduce such a possibility that the number of entry-waiting transport vehicles in either of the pre-junction sections is too large, and this influences the movement of other transport vehicles in a section on the upstream side from the pre-junction section. This accordingly makes it possible to easily restrain the occurrence of a traffic jam in the section on the upstream side from the pre-junction section.

As one aspect, the control system may be configured to, if N1=N2 in performing the entry permission issuing process, add at least 1 to M and give the entry permission to X entry-waiting transport vehicles among the entry-waiting transport vehicles in that one of the two pre-junction sections which satisfies a predetermined condition.

With this configuration, in the entry permission issuing process, even in a case where the two pre-junction sections have the same number of entry-waiting transport vehicles, the entry permission can be suitably given to the transport vehicles so that the transport vehicles can pass the junction. By giving the entry permission to the transport vehicles by this process, such a possibility is raised that the two pre-junction sections have different numbers of entry-waiting transport vehicles at the time of a subsequent entry permission issuing process. This accordingly makes it possible to repeatedly perform the entry permission issuing process appropriately.

As one aspect, the control system performs at least one of determination on which one of the two pre-junction sections corresponds to the first pre-junction section or calculation of X based on corrected numbers of entry-waiting transport vehicles, the corrected numbers being N1 and N2 so corrected as to be larger as respective lengths of the two pre-junction sections are smaller.

With this configuration, as the length of the pre-junction section is shorter, the entry-waiting transport vehicle in the pre-junction section can more easily acquire the entry permission to enter the junction. This makes is possible to easily reduce such a possibility that a short pre-junction section overflows with entry-waiting transport vehicles and influences the movement of other transport vehicles in a section on the upstream side from the pre-junction section.

As one aspect, in a case where X has a value exceeding a predetermined entry upper limit value, the control system performs the entry permission issuing process with use of the entry upper limit value instead of X.

With this configuration, it is possible to avoid the entry permission number X from having a very large value, thereby making it possible to avoid such a situation that the entry-waiting transport vehicles in the second pre-junction section cannot enter the junction for an excessively long time.

As one aspect, the control system acquires information on an entry-permittable number indicative of the number of transport vehicles allowed to enter the post-junction section, and in a case where X has a value exceeding the entry-permittable number, the control system performs the entry permission issuing process with use of a value equal to or less than the entry-permittable number instead of X.

With this configuration, it is possible to avoid the post-junction section from having a traffic jam. In a case where a branch is disposed between an entry-waiting transport vehicle and the post-junction section, the entry-waiting transport vehicle can selectively detour around the post-junction section. This accordingly makes it possible to increase transport efficiency by the transport vehicle.

As one aspect, after the control system performs the entry permission issuing process and all the entry-waiting transport vehicles receiving the entry permission by the entry permission issuing process exit from the first pre-junction section, the control system performs a subsequent entry permission issuing process.

In this configuration, since the entry permission issuing process is performed repeatedly, the entry permission can be suitably given to transport vehicles entering the pre-junction section one after another so that the transport vehicles are allowed to pass the junction. In the above configuration, after all the transport vehicles receiving the entry permission by the previous entry permission issuing process exit from the first pre-junction section, the subsequent entry permission issuing process is performed. Accordingly, the subsequent entry permission issuing process can be performed appropriately in consideration of the number of transport vehicles entering the pre-junction section after the previous entry permission issuing process.

The article transport facility according to this disclosure should be able to achieve at least one of the above effects. The technical feature of the article transport facility according to this disclosure is also applicable to an article transport method and an article transport program.

What is claimed is:

1. An article transport facility, comprising:
a plurality of transport vehicles each configured to move along a predetermined path and transport an article; and
a control system configured to control the plurality of transport vehicles, and
wherein:
the path comprises a junction at which two pre-junction sections are merged into one post-junction section,
the two pre-junction sections comprise a first pre-junction section and a second pre-junction section, the first pre-junction section having more entry-waiting transport vehicles waiting to enter the junction than the second pre-junction section, and
the control system is configured to perform an entry permission issuing process of giving an entry permission to enter the junction to X entry-waiting transport vehicles among the entry-waiting transport vehicles in the first pre-junction section,
wherein X=N1−N2+M,
where X is the number of entry-waiting transport vehicles receiving the entry permission, N1 is a first number indicative of the number of the entry-waiting transport vehicles in the first pre-junction section, N2 is a second number indicative of the number of entry-waiting transport vehicles in the second pre-junction section, and M is an adjustment number as a numeral of 0 or more.

2. The article transport facility according to claim 1, wherein:
the control system is configured to, if N1=N2 in performing the entry permission issuing process, add at least 1 to M and give the entry permission to X entry-waiting transport vehicles among the entry-waiting transport vehicles in that one of the two pre-junction sections which satisfies a predetermined condition.

3. The article transport facility according to claim 1, wherein:
the control system performs at least one of determination on which one of the two pre-junction sections corresponds to the first pre-junction section or calculation of X based on corrected numbers of entry-waiting transport vehicles, the corrected numbers comprising N1 and N2 so corrected as to be larger as respective lengths of the two pre-junction sections are smaller.

4. The article transport facility according to claim 1, wherein:
in a case where X has a value exceeding a predetermined entry upper limit value, the control system performs the entry permission issuing process with use of the entry upper limit value instead of X.

5. The article transport facility according to claim 1, wherein:
the control system acquires information on an entry-permittable number indicative of the number of transport vehicles allowed to enter the post-junction section, and
in a case where X has a value exceeding the entry-permittable number, the control system performs the entry permission issuing process with use of a value equal to or less than the entry-permittable number instead of X.
